(19) United States
(12) Patent Application Publication
(10) Pub. No.: US 2026/0283006 A1
(43) Pub. Date: Sep. 17, 2026

(54) SEMICONDUCTOR STRUCTURE, SEMICONDUCTOR PACKAGE, AND METHOD FOR FORMING SEMICONDUCTOR STRUCTURE

(71) Applicant: CXMT Corporation, Hefei (CN)

(72) Inventor: Ying Liu, Hefei (CN)

(73) Assignee: CXMT Corporation, Hefei (CN)

(21) Appl. No.: 19/407,317

(22) Filed: Dec. 3, 2025

Related U.S. Application Data
(63) Continuation of application No. PCT/CN2025/131564, filed on Oct. 31, 2025.

(30) Foreign Application Priority Data
Mar. 17, 2025 (CN) 202510310770.4

(51) Int. Cl. H10W 74/10; H10W 90/00; H10W 72/00; H10W 72/20; H10W 72/29; H10W 90/26

(52) U.S. Cl. CPC H10W 74/137; H10W 90/00; H10W 72/01235; H10W 72/01251; H10W 72/01257; H10W 72/07254; H10W 72/222; H10W 72/224; H10W 72/247; H10W 72/29; H10W 72/823; H10W 90/26; H10W 90/722

(57) ABSTRACT

Embodiments of the present disclosure provide a semiconductor structure, a semiconductor package, and a method for forming a semiconductor structure. The semiconductor structure includes a first surface provided with a first conductive pad and a first isolation layer, the first isolation layer at least partially exposing the surface of the first conductive pad; a first connection layer disposed on the surface of the first conductive pad exposed to the first isolation layer and on the first isolation layer; and a first conductive bump disposed on the first connection layer and disposed corresponding to the first conductive pad. An absolute value of a difference between a width of the first conductive pad and a width of the first connection layer is greater than an absolute value of a difference between the width of the first conductive pad and a width of the first conductive bump.

### CROSS-REFERENCE TO RELATED APPLICATIONS

The present disclosure is a continuation of International Patent Application No. PCT/CN2025/131564, filed on Oct. 31, 2025, which claims priority to Chinese Patent Application No. 202510310770.4 filed with China National Intellectual Property Administration on Mar. 17, 2025 and entitled “SEMICONDUCTOR STRUCTURE, SEMICONDUCTOR PACKAGE, AND METHOD FOR FORMING SEMICONDUCTOR STRUCTURE”, the content of which is incorporated herein by reference in its entirety.

### TECHNICAL FIELD

Embodiments of the present disclosure relate to the technical field of semiconductors, and in particular, to a semiconductor structure, a semiconductor package, and a method for forming a semiconductor structure.

### BACKGROUND

As the integration level of the chip increases, the density of devices in the chip becomes increasingly higher. To achieve the functions of the chip, there is a need to achieve internal interconnection among these devices and interconnection between the chip and the outside of the chip. The internal interconnection of the chip mainly refers to metal wiring layers located inside the chip, while the interconnection between the chip and the outside of the chip mainly refers to conductive bumps interconnected with the wiring layers inside the chip. These conductive bumps are exposed on the top of the chip, and solder may be disposed on the exposed surfaces. The conductive bumps are connected to other chips or circuit boards through the solder.

Structurally, the conductive bumps that achieve the interconnection between the chip and the outside include the bumps themselves and an under bump metallurgy (under bump metallurgy, UBM) layer located between the bumps and the metal wirings inside the chip. During the formation of the UBM layer, the UBM layer is often undercut due to the isotropic etching characteristic, which leads to a gap present between the bump and the chip. The existence of the gap affects the reliability of the subsequent process, and even leads to the failure to establish an effective electrical connection between the bumps and the metal wirings inside the chip.

### SUMMARY

Embodiments of the present disclosure provide a semiconductor structure with a higher yield and a method for forming the same.

The problems to be solved by the technical spirit of the present disclosure are not limited to the above-mentioned problems, and those skilled in the art will clearly understand other unmentioned problems from the following description.

Some embodiments of the present disclosure provide a semiconductor structure, which includes: a first surface provided with a first conductive pad and a first isolation layer, the first isolation layer at least partially exposing a surface of the first conductive pad; a first connection layer disposed on the surface of the first conductive pad exposed to the first isolation layer and on the first isolation layer; and a first conductive bump disposed on the first connection layer and disposed corresponding to the first conductive pad. In a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width.

In the embodiments of the present disclosure, the absolute value of the difference between the first width and the third width is less than an absolute value of a difference between the second width and the third width.

In the embodiments of the present disclosure, in the cross section, the first conductive pad exposed by the first isolation layer is provided with a fourth width, and the fourth width is greater than 1/2 of the first width.

In the embodiments of the present disclosure, the semiconductor structure further includes a first solder layer, and the first solder layer is at least formed on the first isolation layer and is adjacent to the first connection layer.

In the embodiments of the present disclosure, the first solder layer covers a surface of the first conductive bump.

In the embodiments of the present disclosure, the semiconductor structure is further provided with a second surface, the second surface being opposite to the first surface, and the second surface being provided with a second conductive pad and a second isolation layer surrounding the second conductive pad; a second connection layer disposed on the second conductive pad and on the second isolation layer; a second conductive bump disposed on the second connection layer and disposed corresponding to the second conductive pad, in a cross section perpendicular to the second surface, a width of the second connection layer being less than a width of the second conductive bump; and a second solder layer at least formed on the second isolation layer and adjacent to the second connection layer.

The embodiments of the present disclosure further provide a semiconductor package including a plurality of semiconductor structures connected to each other, each of the plurality of semiconductor structures including: a first surface, the first surface being provided with a first conductive pad and a first isolation layer, and the first isolation layer at least partially exposing a surface of the first conductive pad; a first connection layer disposed on the surface of the first conductive pad exposed to the first isolation layer, the first connection layer being further disposed on the first isolation layer; and a first conductive bump, the first conductive bump being disposed on the first connection layer and disposed corresponding to the first conductive pad. In a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width; first surfaces of at least two adjacent semiconductor structures are directly opposite to each other and are electrically connected through respective first conductive bumps.

In the embodiments of the present disclosure, in each of the plurality of semiconductor structures, the absolute value of the difference between the first width and the third width is less than an absolute value of a difference between the second width and the third width.

In the embodiments of the present disclosure, the package further includes: a first solder layer disposed between the first conductive bumps of the at least two adjacent semiconductor structures whose first surfaces are directly opposite to each other, and the first solder layer is further formed on first isolation layers of the at least two adjacent semiconductor structures and is adjacent to first connection layers.

In the embodiments of the present disclosure, each of the plurality of semiconductor structures is further provided with a second surface opposite to the first surface, the package further includes that second surfaces of at least two adjacent semiconductor structures are directly opposite to each other, a first spacing is provided between the at least two adjacent semiconductor structures whose first surfaces are directly opposite to each other, a second spacing is provided between the at least two adjacent semiconductor structures whose second surfaces are directly opposite to each other, and in a direction in which the semiconductor structures are connected to each other, the first spacing is greater than the second spacing.

In the embodiments of the present disclosure, the second surface of each of the semiconductor structures is provided with a second conductive pad and a second isolation layer surrounding the second conductive pad; a second connection layer, the second connection layer being disposed on the second conductive pad and on the second isolation layer; and a second conductive bump, the second conductive bump being disposed on the second connection layer and disposed corresponding to the second conductive pad, in a cross section perpendicular to the second surface, a width of the second connection layer being less than a width of the second conductive bump; the package further includes a second solder layer disposed between the at least two adjacent semiconductor structures whose second surfaces are directly opposite to each other, and the second solder layer is further formed on second isolation layers of the at least two adjacent semiconductor structures and is adjacent to second connection layers.

In the embodiments of the present disclosure, the first surface is a front surface of the semiconductor structure, and the second surface is a back surface of the semiconductor structure.

The embodiments of the present disclosure further provide a method for forming a semiconductor structure, which includes: providing a semiconductor base substrate, and disposing a first conductive pad and a first isolation layer covering a part of the first conductive pad on the base substrate to form a first surface; forming an initial first connection layer on the first surface, the initial first connection layer covering surfaces of the first conductive pad and the first isolation layer; forming a first conductive bump on the initial first connection layer, the first conductive bump being disposed corresponding to the first conductive pad; and removing a part of the initial first connection layer, and retaining a part of the initial first connection layer located between the first conductive bump and the first conductive pad to form a first connection layer. In a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width.

In the embodiments of the present disclosure, before or after removing the part of the initial first connection layer, the method further includes: treating a side wall of the first conductive bump and an exposed surface of the first isolation layer with plasma, the side wall of the first conductive bump being treated with microwave plasma, and the exposed surface of the first isolation layer being treated with radio frequency plasma.

In the embodiments of the present disclosure, a first solder layer is formed on the first conductive bump, and the first solder layer is reflowed such that the first solder layer is at least formed on the first isolation layer and is adjacent to the first connection layer.

In the semiconductor structure according to the embodiments of the present disclosure, by controlling a width range among the first conductive pad, the first connection layer, and the first conductive bump, a relatively large gap is present between the first connection layer and the first conductive bump, and a width range of the gap is controlled between 1.5 micrometers and 2.5 micrometers. The relatively large gap may enable the subsequently applied sealing layer to fully fill the gap, thereby avoiding incomplete sealing and formation of holes.

### BRIEF DESCRIPTION OF DRAWINGS

The drawings, which are incorporated in and constitute a part of this specification, illustrate embodiments consistent with the embodiments of the present disclosure and, together with the specification, serve to explain the principles of the embodiments of the present disclosure.

FIG. 1 is a schematic cross-sectional view of a semiconductor structure according to an embodiment of the present disclosure;

FIG. 2 is a schematic cross-sectional view of a semiconductor structure according to an embodiment of the present disclosure;

FIG. 3 is a schematic cross-sectional view of a semiconductor structure according to an embodiment of the present disclosure;

FIG. 4 is a schematic cross-sectional view of a semiconductor structure according to an embodiment of the present disclosure;

FIG. 5 is a schematic cross-sectional view of a semiconductor structure according to an embodiment of the present disclosure;

FIG. 6 is a schematic cross-sectional view of a semiconductor structure according to an embodiment of the present disclosure;

FIG. 7 is a schematic cross-sectional view of a semiconductor structure according to an embodiment of the present disclosure;

FIG. 8 is a schematic cross-sectional view of a semiconductor structure according to an embodiment of the present disclosure;

FIG. 9 is a schematic cross-sectional view of a semiconductor structure according to an embodiment of the present disclosure;

FIG. 10 is a schematic cross-sectional view of a semiconductor package according to an embodiment of the present disclosure;

FIG. 11 is a schematic cross-sectional view of a semiconductor package according to an embodiment of the present disclosure;

FIG. 12 is a schematic flowchart of a method for forming a semiconductor structure according to an embodiment of the present disclosure;

FIG. 13 is a schematic cross-sectional view of a semiconductor structure corresponding to a process of forming the semiconductor structure;

FIG. 14 is a schematic cross-sectional view of a semiconductor structure corresponding to a process of forming the semiconductor structure;

FIG. 15 is a schematic cross-sectional view of a semiconductor structure corresponding to a process of forming the semiconductor structure;

FIG. 16 is a schematic cross-sectional view of a semiconductor structure corresponding to a process of forming the semiconductor structure; and

FIG. 17 is a schematic cross-sectional view of a semiconductor structure corresponding to a process of forming the semiconductor structure.

Through the above drawings, explicit embodiments of the embodiments of the present disclosure have been illustrated, and more detailed descriptions will follow. These drawings and textual descriptions are not intended to limit the scope of the inventive concept of the embodiments of the present disclosure in any way, but rather to explain the concepts of the embodiments of the present disclosure to those skilled in the art by referring to specific embodiments.

### DESCRIPTION OF EMBODIMENTS

The technical solutions in embodiments of the present disclosure will be clearly and completely described hereinafter with reference to the drawings in the embodiments of the present disclosure. It can be understood that the specific embodiments described herein are merely illustrative of the related disclosures and are not intended to limit the present disclosure. In addition, it should be further noted that for the convenience of description, only the relevant portions are shown in the drawings. Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure. In the following description, reference is made to “some embodiments”, which describe subsets of all possible embodiments, but it can be understood that “some embodiments” may be the same subset or different subsets of all possible embodiments, and may be combined with each other without conflict. It should be noted that the terms “first\second\third” referred to in the embodiments of the present disclosure are merely used for distinguishing similar objects and do not represent a specific ordering for the objects.

The semiconductor structures according to the embodiments of the present disclosure are described in detail below with reference to the corresponding drawings.

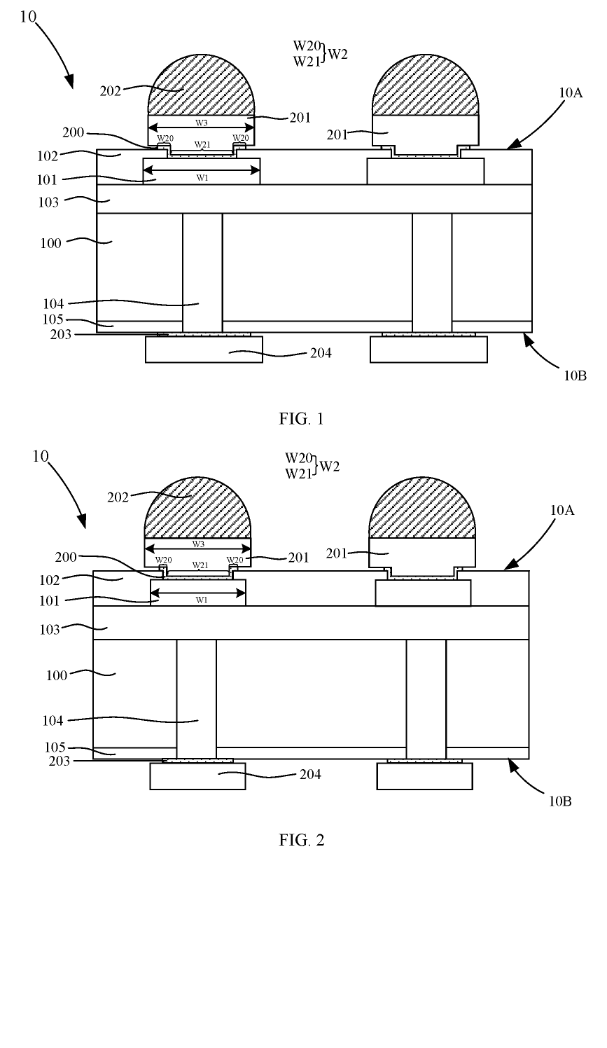

Referring first to FIGS. 1 and 2, FIGS. 1 and 2 are schematic cross-sectional views of semiconductor structures according to some embodiments of the present disclosure. A semiconductor structure 10 includes a semiconductor base substrate 100. A first conductive pad 101 and a first isolation layer 102 are disposed on the semiconductor base substrate 100. The first isolation layer 102 covers a part of the surface of the first conductive pad 101, and another part of the surface of the first conductive pad 101 is not covered by the first isolation layer 102; that is, the first isolation layer 102 at least partially exposes the surface of the first conductive pad 101. The first isolation layer 102 and the exposed surface of the first conductive pad 101 form a first surface 10A of the semiconductor structure 10.

The semiconductor structure 10 further includes a first connection layer 200 disposed on the first surface 10A. The first connection layer 200 includes a part disposed on the surface of the first conductive pad 101 exposed to the first isolation layer 102, and a part disposed on the surface of the first isolation layer 102 The semiconductor structure 10 further includes a first conductive bump 201. The first conductive bump 201 is disposed on the first connection layer 200 and is disposed corresponding to the first conductive pad 101, and the first conductive bump 201 is electrically connected to the first conductive pad 101 through the first connection layer 200.

In the above embodiments, in a cross section perpendicular to the first surface 10A, the first conductive pad 101 is provided with a first width W1, the first connection layer 200 is provided with a second width W2, and the first conductive bump 201 is provided with a third width W3. The width W2 of the first connection layer 200 is a sum of a width W20 of a part located on the first isolation layer 102 and a width W21 of a part located on the exposed surface of the first conductive pad 101. An absolute value of a difference between the first width W1 and the second width W2 is greater than an absolute value of a difference between the first width W1 and the third width W3.

In some embodiments described above, the cross section perpendicular to the first surface 10A is a cross section formed by cutting along the center axis of the first conductive pad 101 or the first conductive bump 201. In this case, the first width W1 is the maximum width of the first conductive pad 101 on the cross section in the direction perpendicular to the first surface 10A, the second width W2 is the maximum width of the first connection layer 200 on the cross section in the direction perpendicular to the first surface 10A, and the third width W3 is the maximum width of the first conductive bump 201 on the cross section in the direction perpendicular to the first surface 10A.

In some embodiments described above, the first width W1 is greater than the second width W2, the first width W1 may be greater than or less than the third width W3, and the second width W2 is less than the third width W3. As shown in FIG. 1, the first width W1 is greater than the second width W2 and the third width W3, and the second width W2 is less than the third width W3. In this case, the difference between the first width W1 and the second width W2 is greater than the difference between the first width W1 and the third width W3. In some other embodiments described above, as shown in FIG. 2, the first width W1 is greater than the second width W2 and is less than the third width W3, and the second width W2 is less than the third width W3. In this case, the absolute value of the difference between the first width W1 and the second width W2 is greater than the absolute value of the difference between the first width W1 and the third width W3.

In the above embodiments, the absolute value of the difference between the first width W1 and the second width W2 is within 3 micrometers to 5 micrometers, for example, may be within 3 micrometers to 3.5 micrometers, 3.5 micrometers to 4 micrometers, 4 micrometers to 4.5 micrometers, 4.5 micrometers to 5 micrometers, or the like. The absolute value of the difference between the first width W1 and the third width W3 is within 1 micrometer to 3 micrometers, for example, may be within 1 micrometer to 1.5 micrometers, 1.5 micrometers to 2 micrometers, 2 micrometers to 2.5 micrometers, 2.5 micrometers to 3 micrometers, or the like.

In some embodiments described above, as shown in FIGS. 1 and 2, a height difference is present between the surface of the first isolation layer 102 and the exposed surface of the first conductive pad 101; that is, the surface of the first isolation layer 102 is higher than the exposed surface of the first conductive pad 101. Further, the first surface 10A of the semiconductor structure 10 is provided with a stepped surface, and the first connection layer 200 covers the stepped surface. In some embodiments, the surface of the first connection layer 200 located on the surface of the first conductive pad 101 is lower than the surface of the first connection layer 200 located on the surface of the first isolation layer 102. That is, there is a recess in a region of the first connection layer 200 corresponding to the first conductive pad 101, and the first conductive bump 201 fills the recess and protrudes from the surface of the first connection layer 200.

In the above embodiments, the semiconductor base substrate 100 may be made of or may include various types of semiconductor materials, which include, for example, silicon, germanium, group III-V elements, or another type of suitable material. A device layer 103 is further provided between the semiconductor base substrate 100 and the first conductive pad 101, and the device layer 103 is provided with semiconductor devices and a metal interconnect layer for achieving the interconnection of the semiconductor devices. The semiconductor device may include a transistor and a capacitor connected to the transistor, for example, a DRAM device unit. The type of the semiconductor device is not limited, and the semiconductor device may also be another type of semiconductor device. The metal interconnect layer may be a conductive path that interconnects the semiconductor devices to form a functional circuit and connects the semiconductor devices to external units. The metal interconnect layer may include one or more layers of metal wirings.

In the above embodiments, the first conductive pad 101 may be a topmost metal wiring layer, for example, may be an aluminum wiring layer or a copper wiring layer, interconnected with the metal interconnect layer in the device layer 103.

In the above embodiments, the first isolation layer 102 may be a passivation layer, and the first isolation layer may be made of silicon nitride, silicon dioxide, polyimide, or the like.

In the above embodiments, the first connection layer 200 may be a UBM layer, which may be a single conductive layer or a composite conductive layer composed of two or more conductive layers. The first connection layer 200 may be made of one of or a combination of more than one of metals such as titanium, copper, nickel, cobalt, or gold. When the first connection layer 200 is a composite layer, for example, when the first connection layer 200 is a composite layer of a titanium layer and a copper layer, the second width W2 of the first connection layer 200 may be an average value of widths of the layers.

In the above embodiments, the first conductive bump 201 may be in a cylindrical shape, a rectangular shape, a trapezoidal shape, an inverted trapezoidal shape, or the like, and may be made of a conductive metal such as copper, nickel, or gold.

In some embodiments, with continued reference to FIGS. 1 and 2, the semiconductor structure 10A further includes a first solder layer 202 disposed on the first conductive bump 201, and the first solder layer 202 wraps the top surface of the first conductive bump 201, to form a solder joint on the surface of the first conductive bump 201.

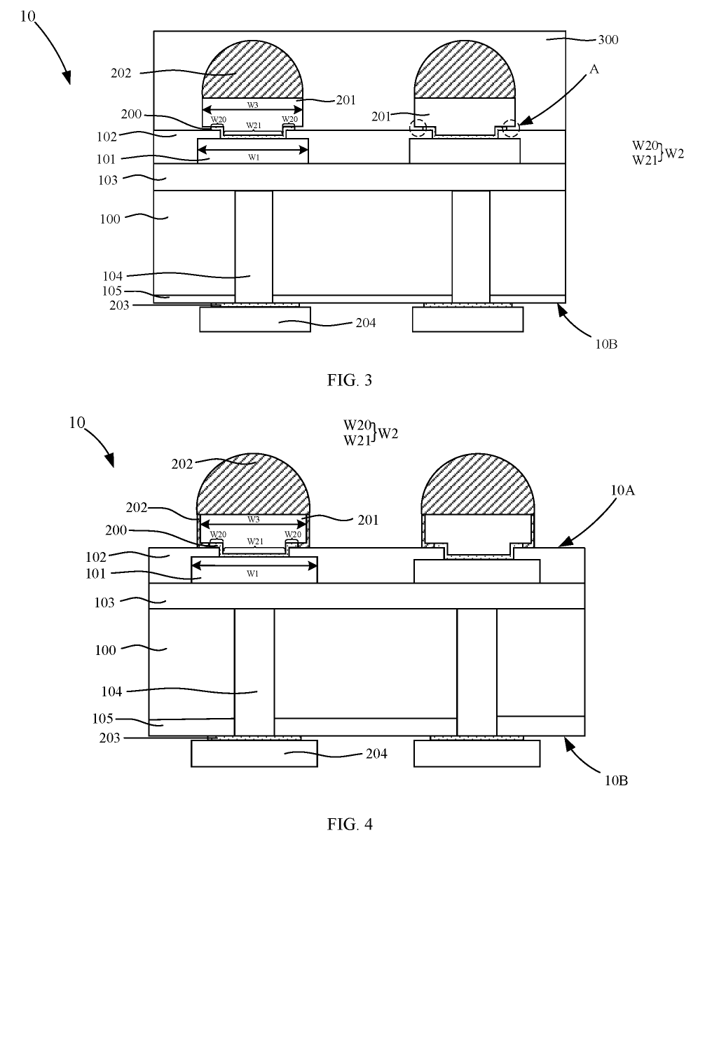

In some embodiments, upon soldering the first conductive bump 201 using the first solder layer 202, the semiconductor structure 10A further includes a sealing layer. As shown in FIG. 3, FIG. 3 is a schematic cross-sectional view of a semiconductor structure according to some embodiments of the present disclosure. The sealing layer 300 wraps the exposed surfaces of the first isolation layer 102, the first connection layer 200, the first conductive bump 201, and the first solder layer 202, to isolate adjacent first conductive bumps 201 and first solder layers 202, thereby providing the insulation and protection for the first conductive bumps 201 and the first solder layers 202. The sealing layer 300 may also be formed in the semiconductor structure shown in FIG. 2. FIG. 3 illustrates a forming position of the sealing layer on the basis of FIG. 1, but does not constitute a limitation on the position of the sealing layer 300. The sealing layer 300 may be a plastic encapsulating material, a non-conductive film (NCF), or another type of insulating sealing material.

With continued reference to FIG. 3, in the above embodiments, due to the difference in width between the first connection layer 200 and the first conductive bump 201, a gap A is present between the first connection layer and the first conductive bump, and the gap A exposes the surface of the first isolation layer 102. The reason for the presence of the gap A is that during the formation of the first connection layer, since the first conductive bump and the first connection layer are made of different materials, there is a difference in etching selectivity, resulting in the first connection layer being etched more than the first conductive bump. However, generally, the presence of the gap A is undesirable, and a width of the gap A is controlled within a relatively small range, for example, less than 1 micrometer. This is because, if the width of the gap A is excessively large, a loss of the first connection layer may be caused, thereby increasing the connection resistance and reducing the adhesion between the first conductive bump and the first conductive pad. However, if the gap A is excessively small, although the aforementioned drawbacks can be overcome, with the miniaturization of the semiconductor structure, the excessively small gap A may make it difficult for the subsequently applied sealing layer, which provides sealing and isolation, to fully fill the gap A, thereby resulting in an interspace present between the first conductive bump and the first isolation layer in the finally packaged semiconductor structure. This affects the electrical performance and the mechanical strength of the first conductive bump.

In the semiconductor structure according to the embodiments of the present disclosure, by controlling a width range among the first conductive pad, the first connection layer, and the first conductive bump, a relatively large gap A is present between the first connection layer and the first conductive bump, and a width range of the gap A is controlled between 1.5 micrometers and 2.5 micrometers. The relatively large gap may enable the subsequently applied sealing layer 300 to fully fill the gap, thereby avoiding incomplete sealing and formation of holes. In addition, the problem of increased resistance caused by the loss of the first connection layer due to the relatively large gap A and the problem of the connection strength with the first conductive pad may be solved by appropriately increasing the width of the first conductive bump and increasing the surface area of the surface of the first conductive pad exposed to the first isolation layer. That is, by reducing the difference between the first width W1 and the third width W3, the width W21 of the part, of the first connection layer, located on the exposed surface of the first conductive pad is increased, and the width W20 of the part, of the first connection layer, located on the first isolation layer is reduced.

In some embodiments, as shown in FIGS. 1 to 3, the surface of the first conductive pad 101 exposed by the first isolation layer 102 is provided with a fourth width (not shown in the figures), and the fourth width is the width W21 of the part of the first connection layer 200 on the surface of the first conductive pad 101. The fourth width is greater than 1/2 of the first width W1. In some embodiments, the fourth width is not less than 5/7, 3/4, 6/7, or the like of the first width W1.

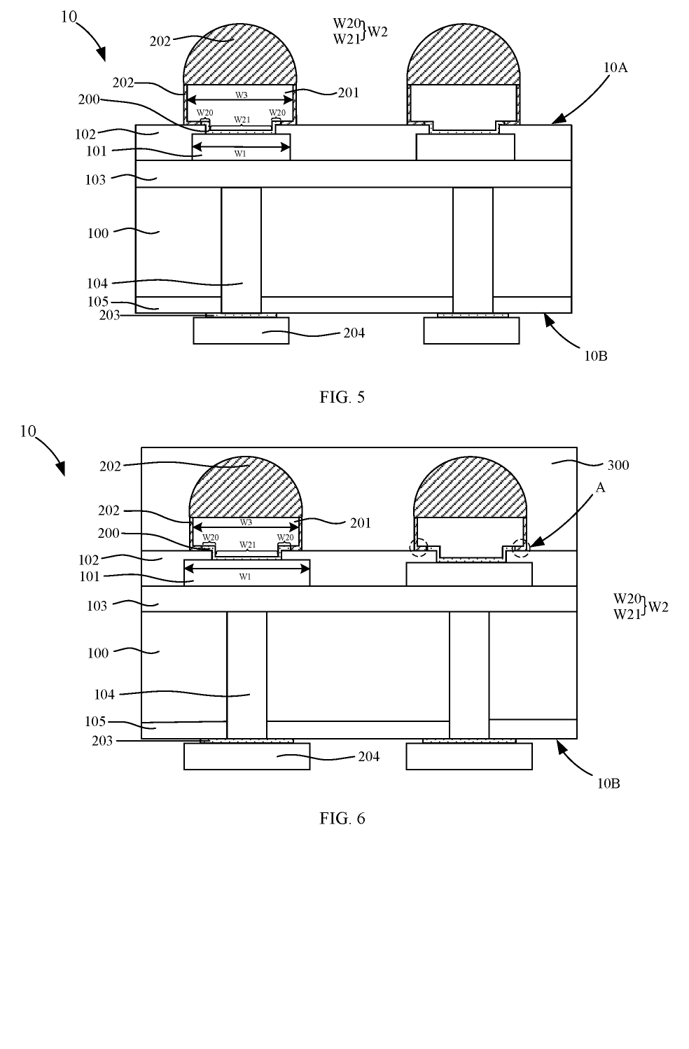

The embodiments of the present disclosure further provide a semiconductor structure. Specifically referring to FIGS. 4 and 5. FIGS. 4 and 5 are schematic cross-sectional views of semiconductor structures according to the embodiments of the present disclosure.

The semiconductor structures according to FIGS. 4 and 5 are described in detail below. The semiconductor structures 10 according to FIGS. 4 and 5 each include the semiconductor base substrate 100, the device layer 103 disposed on the semiconductor base substrate 100, the first conductive pad 101 located on the device layer 103 and electrically connected to the device layer 103, and the first isolation layer 102 partially covering the first conductive pad 101. The first connection layer 200 is disposed on parts of the surfaces of the first conductive pad 101 and the first isolation layer 102, the first conductive bump 201 corresponding to the surface of the first conductive pad 101 exposed to the first isolation layer 102 is disposed on the first connection layer 200, and the first conductive bump 201 is electrically connected to the first conductive pad 101 through the first connection layer 200. In the embodiment shown in FIG. 4, the first width W1 is greater than the second width W2 and the third width W3, and the second width W2 is less than the third width W3. In this case, the difference between the first width W1 and the second width W2 is greater than the difference between the first width W1 and the third width W3. In the embodiment shown in FIG. 5, the first width W1 is greater than the second width W2 and is less than the third width W3, and the second width W2 is less than the third width W3. In this case, the difference between the first width W1 and the second width W2 is greater than the absolute value of the difference between the first width W1 and the third width W3.

The other parts of the semiconductor base substrate 100, the first conductive pad 101, the first isolation layer 102, the first connection layer 200, and the first conductive bump 201 not described in detail are the same as the corresponding parts in the embodiments shown in FIGS. 1 and 2, and are not described herein again. The range of differences between the widths is also the same as the corresponding range of differences in the embodiments shown in FIGS. 1 and 2.

With continued reference to FIGS. 4 and 5, the semiconductor structure 10 further includes the first solder layer 202. The first solder layer 202 includes a part formed on the top surface of the first conductive bump 201 and a part formed on the surface of the first isolation layer 102 and adjacent to the first connection layer 200. In some embodiments, the first solder layer 202 is further formed on the side wall of the first conductive bump 201.

With continued reference to FIG. 6, the semiconductor structure 10 further includes the sealing layer 300. The sealing layer 300 covers the surface of the first solder layer 202, and isolates the adjacent first conductive bumps 201. In the embodiment shown in FIG. 6, the first solder layer 202 is formed in the gap A between the first connection layer 200 and the first conductive bump 201 to fully fill the gap A.

In the semiconductor structure according to the above embodiments, the first solder layer fills the space where the first isolation layer corresponds to the first conductive bump, and is adjacent to the first connection layer, thereby further filling the gap A. In addition, the resistance of the first solder layer is less than that of the sealing layer, thereby further reducing the resistance between the first conductive bump and the first conductive pad. Moreover, the first solder layer exhibits better fluidity than the sealing layer, making it more capable of filling the gap A.

In some embodiments, the absolute value of the difference between the first width W1 and the third width W3 is less than an absolute value of a difference between the second width W2 and the third width W3. In the embodiments shown in FIGS. 1 and 3, the first width W1 is greater than the third width W3, the second width W2 is less than the third width W3, and the difference between the first width W1 and the third width W3 is less than the difference between the third width W3 and the second width W2. In the embodiments shown in FIGS. 2 and 4, the first width W1 is less than the third width W3, the second width W2 is less than the third width W3, and the difference between the first width W1 and the third width W3 is less than the difference between the third width W3 and the second width W2. There is a relatively large gap between the first connection layer and the first conductive bump in the semiconductor device according to the above embodiments.

In the above embodiments, the absolute value of the difference between the first width and the third width is between 1 micrometer and 1.5 micrometers, and the absolute value of the difference between the second width and the third width is between 1.5 micrometers and 2.5 micrometers.

With continued reference to FIGS. 1 to 6, in some embodiments, the semiconductor structure 10 is further provided with a second surface 10B. The second surface 10B and the first surface 10A are opposite surfaces, the second surface 10B is provided with a second conductive pad 104 and a second isolation layer 105 surrounding the second conductive pad 104, the second conductive pad 104 may be a TSV via structure penetrating through the semiconductor base substrate 100, or may be another conductive structure extending through the semiconductor base substrate 100, the second isolation layer 105 covers the surface of the semiconductor base substrate 100 proximal to the second surface 10B, and the second isolation layer 105 is configured to isolate a plurality of second conductive pads 104 adjacent to each other.

In the above embodiments, the semiconductor structure 10 further includes a second connection layer 203 disposed on the second surface 10B. The second connection layer 203 is disposed on the second conductive pad 104 and the second isolation layer 105, the second connection layer 203 is disposed corresponding to the second conductive pad 104 and fully covers the surface of the second conductive pad, and the second connection layer 203 further partially covers the surface of the second isolation layer 105. The semiconductor structure 10 further includes a second conductive bump 204. The second conductive bump 204 is disposed corresponding to the second conductive pad 104 and is on the second connection layer 203, and the second conductive bump 204 is electrically connected to the second conductive pad 104 through the second connection layer 203.

In some embodiments described above, in a cross section perpendicular to the second surface B, the second conductive bump 204 and the first conductive bump 201 are provided with the same width or different widths, a width of the second conductive pad 104 is less than widths of the second conductive bump 204 and the second connection layer 203, and a width of the second connection layer 203 is less than a width of the second conductive bump 204; that is, there is a gap between the second connection layer 203 and the surface of the second conductive bump 204 facing the second isolation layer 105.

In the above embodiments, the second conductive bump 204 may be in a cylindrical shape, a rectangular shape, a trapezoidal shape, an inverted trapezoidal shape, or the like, and may be made of a conductive metal such as copper, nickel, or gold.

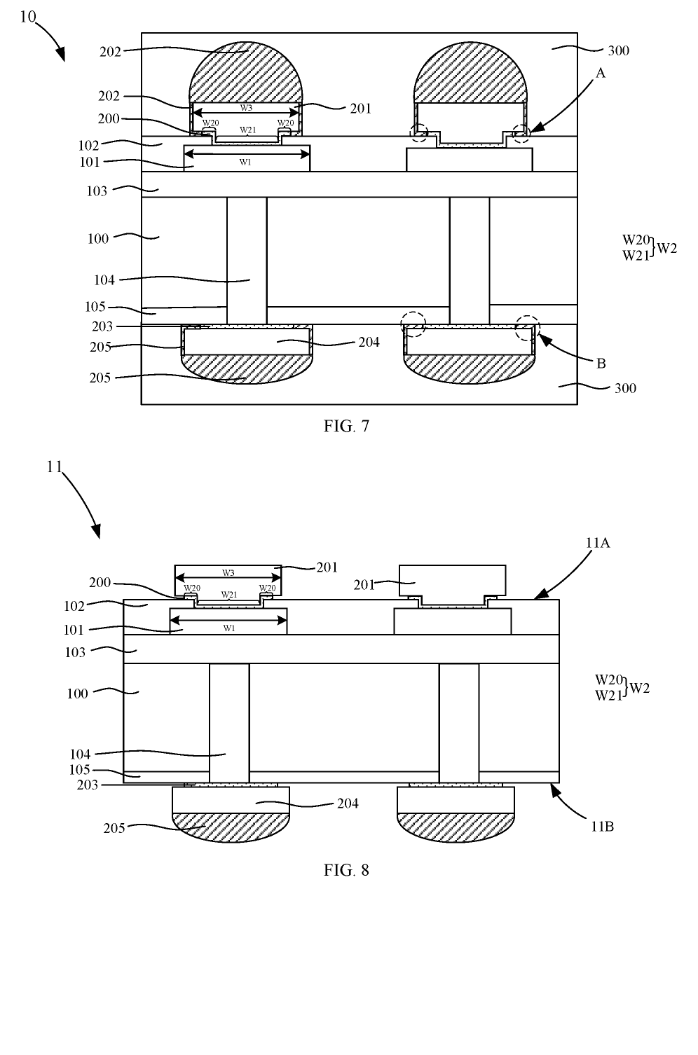

In some embodiments, the semiconductor structure 10 further includes a second solder layer and a sealing layer. As shown in FIG. 7, FIG. 7 is a schematic cross-sectional view of a semiconductor structure according to the embodiments of the present disclosure. The second solder layer 205 is disposed on the second conductive bump 204, the sealing layer 300 wraps the second solder layer 205, and the second solder layer 205 at least wraps the top surface of the second conductive bump 204. In some embodiments, the second solder layer 205 further wraps the side wall surface of the second conductive bump 204. In some embodiments, the second solder layer 205 is further disposed in a gap B among the second connection layer 203, the second conductive bump 204, and the second isolation layer 105. In some embodiments, the second solder layer 205 may be formed only in the gap B. In these embodiments, by filling the gap among the second connection layer, the second conductive bump, and the second isolation layer with the second solder layer, the sealing layer is prevented from failing to effectively fill the gap subsequently, thereby avoiding a decrease in sealing reliability.

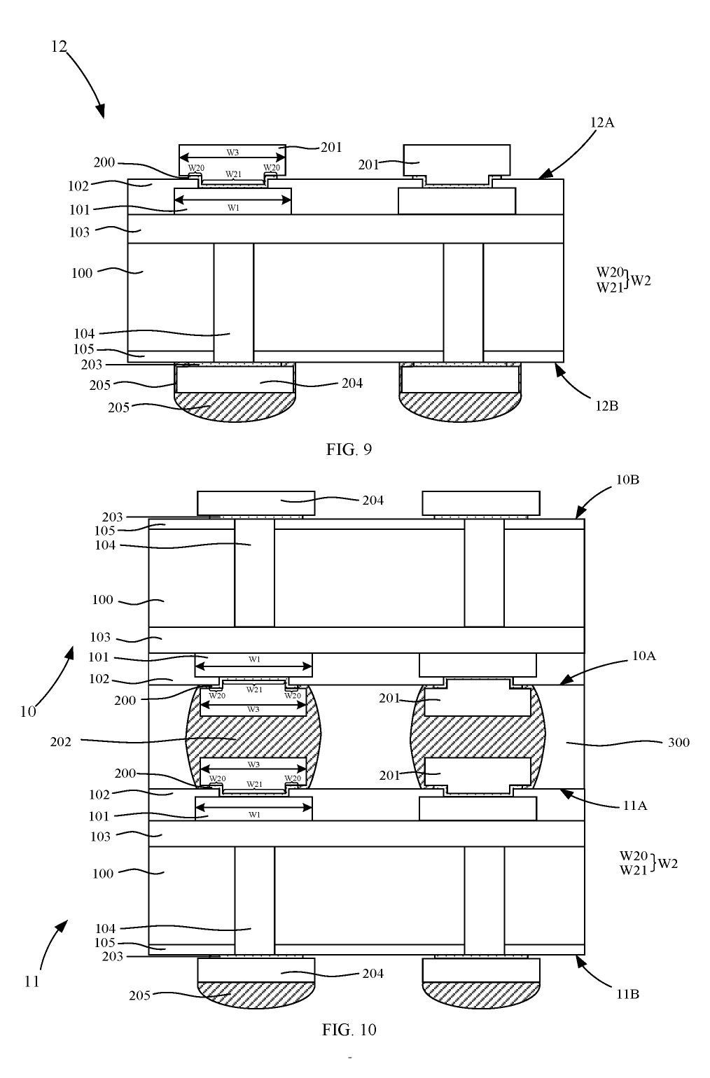

The embodiments of the present disclosure further provide other types of semiconductor structures, as shown in FIGS. 8 and 9. FIGS. 8 and 9 are schematic cross-sectional views of semiconductor structures according to the embodiments of the present disclosure. The embodiments corresponding to FIGS. 8 and 9 provide a semiconductor structure 11 and a semiconductor structure 12. The semiconductor structure 11 includes a first surface 11A and a second surface 11B opposite to the first surface 11A, and the semiconductor structure 12 includes a first surface 12A and a second surface 12B opposite to the first surface 12A. A difference between the semiconductor structure 11 and the semiconductor structure 10 according to the aforementioned embodiments lies in that no first solder layer 202 is disposed on the first conductive bump 201 on the first surface 11A of the semiconductor structure 11; that is, only the surface of the second conductive bump 204 is provided with the second solder layer 205. A difference between the semiconductor structure 12 and the semiconductor structure 10 according to the aforementioned embodiments lies in that no first solder layer 202 is disposed on the first conductive bump 201 on the first surface 12A of the semiconductor structure 12; that is, only the surface of the second conductive bump 204 is provided with the second solder layer 205, and the second solder layer 205 is further disposed in a gap among the second connection layer 203, the second conductive bump 204, and the second isolation layer 105. The position of the second solder layer is not limited to the positions listed above, and the second solder layer may be formed only in the gap among the second connection layer 203, the second conductive bump 204, and the second isolation layer 105, and may be formed both on the side wall of the second conductive bump 204 and in the gap among the second connection layer 203, the second conductive bump 204, and the second isolation layer 105.

In the above embodiments, the first surface 10A of the semiconductor structure 10 may be the front surface of the first semiconductor structure 10, and the second surface 10B is the back surface of the first semiconductor structure 10. Similarly, the first surface and the second surface of the semiconductor structure 11 also correspond to the front surface and the back surface of the semiconductor structure 11, and the first surface and the second surface of the semiconductor structure 12 also correspond to the front surface and the back surface of the semiconductor structure 12. The front surface herein refers to a surface of the semiconductor structure proximal to a back-end metal wiring, which serves to achieve communication and interconnection between a chip and the outside. The back surface herein refers to a surface of the semiconductor structure proximal to the semiconductor base substrate.

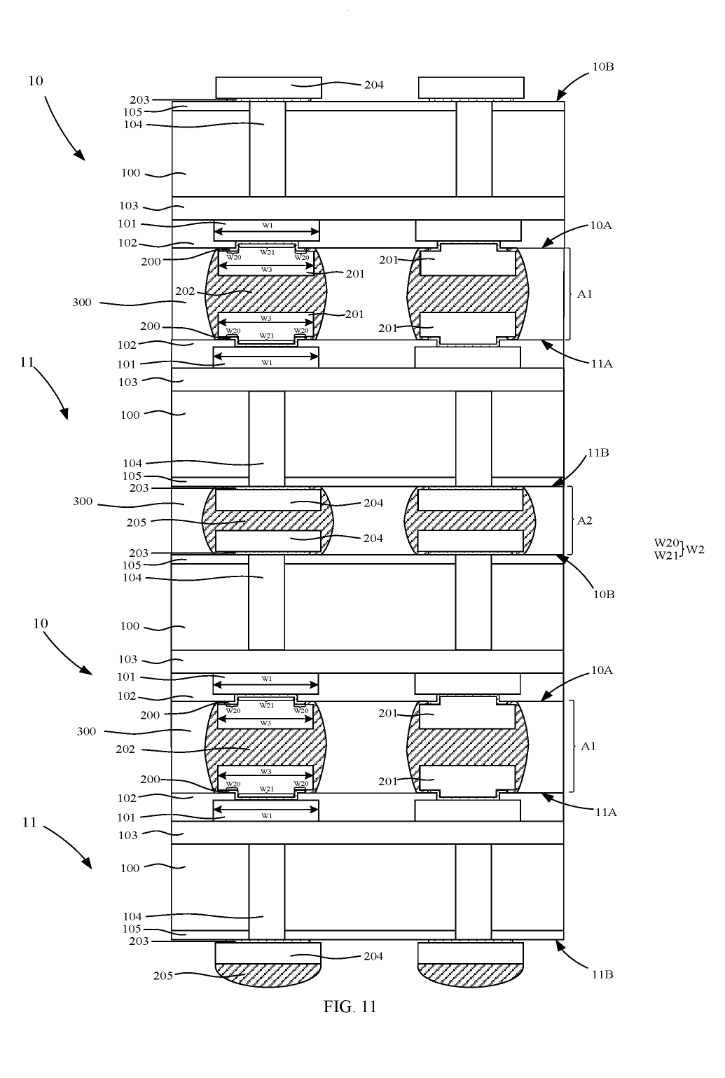

The embodiments of the present disclosure further provide a semiconductor package. FIGS. 10 and 11 show schematic views of structures of semiconductor packages according to some embodiments of the present disclosure. The semiconductor packages are described in detail below with reference to FIGS. 10 and 11.

As shown in FIG. 10, the semiconductor package includes at least one semiconductor structure 10 and a semiconductor structure 11 connected to each other. A first surface 10A of the semiconductor structure 10 is disposed directly opposite to a first surface 11A of the semiconductor structure 11, and a first conductive bump 201 on the first surface 10A and a first conductive bump 201 on the first surface 11A are aligned and connected one-to-one. A first solder layer 202 serves as a connecting medium for the corresponding first conductive bumps 201, thereby achieving the electrical connection between the corresponding first conductive bumps 201. The first solder layer 202 is further formed on first isolation layers 102 of semiconductor chips and is adjacent to first connection layers 200; that is, the first solder layer 202 is also simultaneously formed in a gap among the first isolation layer, the first connection layer, and the first conductive bump on the first surface of each semiconductor structure.

The semiconductor structure 10 in the semiconductor package according to the above embodiments may be the semiconductor structure 10 according to the embodiments corresponding to FIGS. 1 to 7, which has the same or similar structural features as the semiconductor structure 10 in these embodiments. The semiconductor structure 11 in the semiconductor package according to the above embodiments may be the semiconductor structure 11 according to the embodiments corresponding to FIGS. 8 and 9, which has the same or similar structural features as the semiconductor structure 11 in these embodiments.

In these embodiments, the connection between the semiconductor structure 10 and the semiconductor structure 11 can be achieved by thermal compression bonding technology.

In some embodiments described above, during the thermal compression bonding, the first solder layer 202 may be formed only between adjacent first conductive bumps 201; that is, the first solder layer 202 is not formed in the gap among the first isolation layer, the first connection layer, and the first conductive bump.

In some embodiments described above, during the formation of the above package, when the semiconductor structure 10 and the semiconductor structure 11 in the embodiments shown in FIGS. 1 to 3 are connected, the first solder layer 202 may be formed in the gap among the first isolation layer, the first connection layer, and the first conductive bump during the thermal compression bonding. When the semiconductor structure 10 and the semiconductor structure 11 in the embodiments shown in FIGS. 4 to 6 are connected, the first solder layer 202 may be formed before thermal compression bonding, and the gap among the first isolation layer, the first connection layer, and the first conductive bump may be filled by the first solder layer 202 at the same time. During subsequent thermal compression bonding, the first solder layer 202 may allow solder to flow only on the surface of the corresponding first conductive bump 201.

In the semiconductor package according to the above embodiments, the front surfaces of at least two semiconductor structures are bonded with each other, and the back surfaces of the semiconductor structures are exposed. In some embodiments, the method further includes forming a sealing layer 300 between the first surface of the semiconductor structure 10 and the first surface of the semiconductor structure 11.

The embodiments of the present disclosure further provides a package including more than two semiconductor structures. FIG. 11 shows a package including four semiconductor structures, which include two semiconductor structures 10 and two semiconductor structures 11. According to a connection sequence from bottom to top, the first surface 11A of a first semiconductor structure 11 is disposed directly opposite to the first surface 10A of a first semiconductor structure 10, the second surface 10B of the first semiconductor structure 10 is disposed directly opposite to the second surface 11B of a second semiconductor structure 11, and the first surface 11A of the second semiconductor structure 11 is disposed directly opposite to the first surface 10A of the second semiconductor structure 10. The first solder layer 202 is formed between two adjacent semiconductor structures whose first surfaces are directly opposite to each other, and a second solder layer 205 is formed between two adjacent semiconductor structures whose second surfaces are directly opposite to each other.

In the above embodiments, the first surface of each semiconductor structure is a front surface or a back surface, and the second surface is a back surface or a front surface.

In the above embodiments, the method further includes forming the sealing layer 300 between the adjacent semiconductor structures. Sealing layers 300 may be formed together upon connecting the semiconductor structures, or may be first formed on the first surfaces or the second surfaces of the semiconductor structures.

In some embodiments described above, during the thermal compression bonding of the semiconductor structures, the first solder layer 202 and/or the second solder layer 205 may be formed only between the adjacent first conductive bumps 201 and between adjacent second conductive bumps 204. That is, the first solder layer 202 does not fill the gap among the first isolation layer 102, the first connection layer 200, and the first conductive bump 201, and the second solder layer 205 does not fill the gap among the second isolation layer 105, the second connection layer 203, and the second conductive bump 204. These gaps are filled by subsequently formed sealing layers 300.

In some embodiments, with continued reference to FIG. 11, a first spacing A1 is provided between the semiconductor structures whose first surfaces are opposite to each other, and a second spacing A2 is provided between the semiconductor structures whose second surfaces are opposite to each other, and A1 is greater than A2.

In some embodiments, the semiconductor package may further include a package composed of a larger number of semiconductor structures 10 and semiconductor structures 11, or a package formed by connecting only a plurality of semiconductor structures 10 to each other and only a plurality of semiconductor structures 11 to each other, which is not limited in the present disclosure. However, any package that includes the semiconductor structures according to the present disclosure is protected and disclosed by the present disclosure.

In the semiconductor package according to some embodiments of the present disclosure, during the packaging, since the gap between the first connection layer and the first conductive bump and the gap between the second connection layer and the second conductive bump of the semiconductor structures are relatively large, the subsequently formed sealing layers can relatively fully fill these gaps, thereby avoiding the problem of reduced reliability caused by the weak bonding between the conductive bump and the sealing layer.

In the semiconductor package according to some embodiments of the present disclosure, during the packaging or before the packaging, the gap between the first connection layer and the first conductive bump and the gap between the second connection layer and the second conductive bump of the semiconductor structures have been filled and sealed by the first solder layer and the second solder layer, respectively, such that a strong bonding surface is formed, thereby further providing the reliability of the conductive bump on each surface.

In the semiconductor package according to some embodiments of the present disclosure, a front-to-front and back-to-back packaging manner is used, such that the different surfaces of adjacent semiconductor structures are provided with different spacings. This enables the package interconnecting the plurality of semiconductor structures to exhibit good performance in warpage control and packaging stability, thereby allowing the use of a larger number of semiconductor structures in the package.

The method for forming a semiconductor structure according to the present disclosure is further described below with reference to the corresponding drawings.

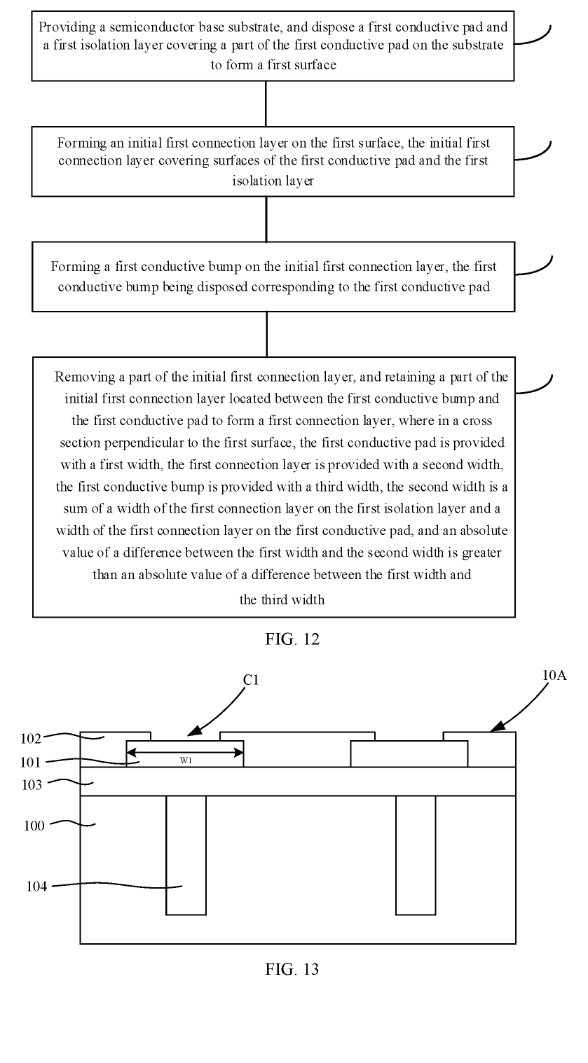

FIG. 12 is a schematic flowchart of forming a semiconductor structure, and FIGS. 13 to 17 are schematic views of semiconductor structures corresponding to process steps.

The method for forming the semiconductor structure includes the following steps: In S11, a semiconductor base substrate is provided, and a first conductive pad and a first isolation layer covering a part of the first conductive pad are disposed on the base substrate to form a first surface.

Referring to FIG. 13, a semiconductor base substrate 100 is provided, a device layer 103 is formed on the semiconductor base substrate 100, and upon forming the device layer 103, a first isolation layer 102 covering the device layer 103 and a first conductive pad 102 interconnected with the device layer 103 are formed. In addition, the first isolation layer 102 also covers a part of the surface of the first conductive pad 101, a gap C1 is formed on the surface of the first conductive pad 101 not covered by the first isolation layer 102, and the first conductive pad 101 is provided with a first width W1 in a direction perpendicular to the semiconductor base substrate 100. The gap C1 at least exposes more than 1/2 of the surface area of the first conductive pad 101. The top surface of the first isolation layer 102 is higher than the exposed top surface of the first conductive pad 101, and the top surface of the first isolation layer 102 and the top surface of the first conductive pad 101 form a first surface 10A of the semiconductor structure.

Step S12 is performed to form an initial first connection layer on the first surface. The initial first connection layer covers the surfaces of the first conductive pad and the first isolation layer.

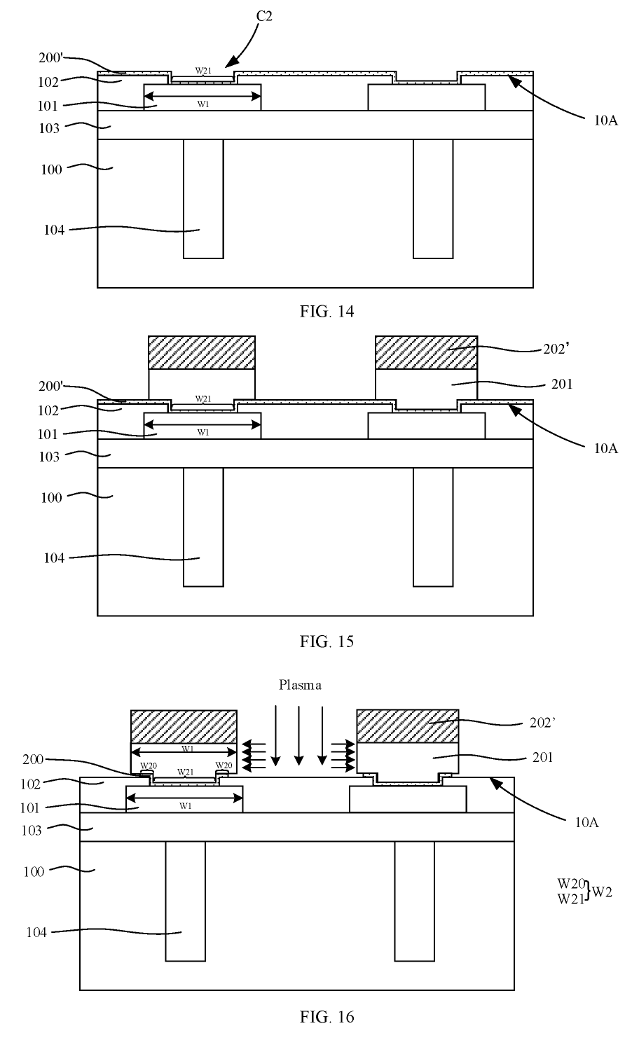

Referring to FIG. 14, an initial first connection layer 200’ is formed on the first surface 10A. The initial first connection layer 200’ covers the surface of the first isolation layer 102 and the exposed surface of the first conductive pad 101, fills the side wall and the bottom surface of the gap C1, and forms a gap C2 on the first conductive pad 101. The initial first connection layer 200’ located on the top surface of the first conductive pad 102 is provided with a width W21, and the width W21 is greater than 1/2 of the first width W1 and less than the first width W1. A process for forming the initial first connection layer 200’ may use methods such as electroplating or deposition.

Step S13 is performed to form a first conductive bump on the initial first connection layer. The first conductive bump is disposed corresponding to the first conductive pad.

Referring to FIG. 15, a first conductive bump 201 is formed on the initial first connection layer 200’, and the first conductive bump 201 includes a part fully filling the gap C2 in FIG. 14 and a part protruding from the initial first connection layer 200’. In addition, the first conductive bump 201 further includes a part formed on the surface of the initial first connection layer 200’ on the surface of the first isolation layer 102. The first conductive bump 201 is disposed corresponding to the first conductive pad 101 and is connected to the first conductive pad through the initial first connection layer 200’ located therebetween.

In the above embodiments, the first conductive bump 201 may be formed by first forming a mask layer on the initial first connection layer 200’, patterning the mask layer to form a pattern of the first conductive bump, filling the pattern region of the first conductive bump through a process such as electroplating or deposition, and then removing the mask layer.

In some embodiments, the first conductive bump 201 is formed, with an initial first solder layer 202’ simultaneously formed on top of the first conductive bump 201.

Step S14 is performed to remove a part of the initial first connection layer, and retain a part of the initial first connection layer located between the first conductive bump and the first conductive pad to form a first connection layer. In a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width.

Referring to FIG. 16, the excess initial first connection layer 200’ on the surface of the first isolation layer 102 is removed by an etching process, and the process for removing a part of the initial first connection layer 200’ may be wet etching, dry etching, or the like. During the etching, the initial first solder layer 202’ and the first conductive bump 201 are also partially etched, but the amounts etched are controlled to be less than the amount etched of the initial first connection layer 200’, and finally, a part of the initial first connection layer 200’ located on the first isolation layer 102 is exposed and is provided with a width of W20, the remaining part of the initial first connection layer forms the first connection layer 200, the first connection layer 200 is provided with a second width W2, and the second width W2 includes the width W20 and the width W21. The finally retained first conductive bump 201 is provided with a third width W3, and the third width W3 is less than the first width W1. In some embodiments, the third width W3 may also be greater than the first width W1. In addition, during the etching, an absolute value of a difference between the first width W1 and the second width W2 is controlled to be greater than an absolute value of a difference between the first width W1 and the third width W3.

By controlling the etching process during the formation of the first conductive bump and the first connection layer, and controlling the dimension of the first conductive pad and the exposed dimension of the first conductive pad, the amount etched of the initial first connection layer is relatively large, thereby forming a relatively large interspace among the first conductive bump, the first connection layer, and the first isolation layer.

With continued reference to FIG. 16, in some embodiments, upon etching the initial first connection layer 200’ to form the first connection layer 200, the exposed side walls between adjacent first conductive bumps 201 and the exposed surface of the first isolation layer 102 are treated with plasma. For example, the exposed side wall of each first conductive bump 201 is treated with microwave plasma in a direction perpendicular to the side wall of the first conductive bump 201, and the exposed surface of the first isolation layer 102 is treated with radio frequency plasma in a direction perpendicular to the surface of the first isolation layer 102. The plasma may be a plasma formed of an inert gas. The microwave plasma refers to a plasma generated by ionizing inert gas molecules under the action of microwave energy. The microwave plasma has advantages such as high density and low temperature. After being treated with the microwave plasma, the side wall of the first conductive bump 201 becomes smooth, and the surface roughness is much lower than that of the side wall of the first conductive bump 201 after the etching. The radio frequency plasma refers to a plasma generated by exciting inert gas molecules into a plasma state using radio frequency energy. The radio frequency plasma is characterized by anisotropic treatment, which can form fine pits on the surface of the first isolation layer 102, thereby increasing the surface roughness of the first isolation layer 102.

In some embodiments, during the formation of the first connection layer 200, the method further includes treating the first connection layer with reactive plasma, which can further reduce the width of the first connection layer 200. The reactive plasma may be an etching gas, such as a Cl₂/BCl₃/Ar mixed gas, that can react with the material of the first connection layer 200.

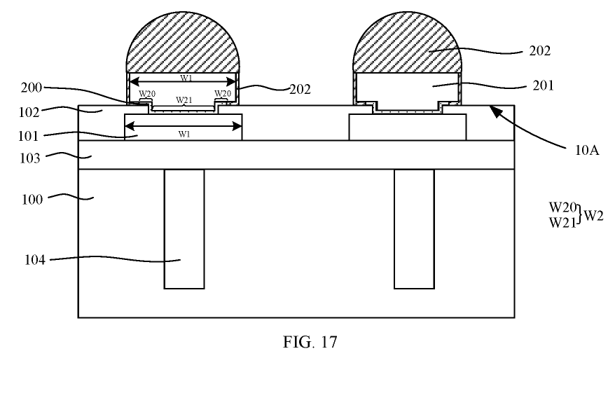

With continued reference to FIG. 17, in some embodiments, upon forming the first connection layer 200, the method further includes performing a reflow process on the initial first solder layer 202’ to form the first solder layer 202. The first solder layer 202 at least wraps the top surface and the side wall of the first conductive bump 201, and is formed on the first isolation layer 102 and is adjacent to the first connection layer 200. That is, the first solder layer 202 further fills the interspace enclosed by the first connection layer 200, the first conductive bump 201, and the surface of the first isolation layer 102. This is because, before the reflow, the side wall of the first conductive bump 201 becomes smoother after being treated with the microwave plasma, thereby helping solder flow into the aforementioned interspace along the side wall of the first conductive bump. In some other embodiments, since the roughness of the surface of the first isolation layer exposed between the adjacent first conductive bumps is increased after being treated with the radio frequency plasma, the flow of the solder between the adjacent first conductive bumps during the reflow can be blocked, thereby avoiding the short circuit between the adjacent first conductive bumps. The surface of the first isolation layer located directly below the first conductive bump is blocked by the first conductive bump and thus is not interfered with by the radio frequency plasma, and the roughness of the surface is not increased, such that the solder can relatively easily enter the region below the first conductive bump and be adjacent to the first connection layer.

In some other embodiments, the flow of the solder may also be blocked by performing an etching process on the surface of the first isolation layer exposed between the adjacent first conductive bumps to form a trench.

Upon forming the first solder layer 202, the method further includes turning over the semiconductor base substrate 100, using another surface of the semiconductor base substrate 100 distal to the first surface 10A as a surface to be processed, thinning the surface to be processed to expose the top surface of a second conductive pad 104, and further forming structures such as a second isolation layer, a second connection layer, and a second conductive bump, to finally obtain the semiconductor structure shown in FIGS. 1 to 6. The processes of forming the second connection layer and the second conductive bump may be similar to the processes of forming the first connection layer and the first conductive bump, and details are not described herein again.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

1. A semiconductor structure, comprising:
a first surface provided with a first conductive pad and a first isolation layer, the first isolation layer at least partially exposing a surface of the first conductive pad;
a first connection layer disposed on the surface of the first conductive pad exposed to the first isolation layer and on the first isolation layer; and
a first conductive bump disposed on the first connection layer and disposed corresponding to the first conductive pad, wherein
in a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width.

2. The semiconductor structure according to claim 1, wherein the absolute value of the difference between the first width and the third width is less than an absolute value of a difference between the second width and the third width.

3. The semiconductor structure according to claim 1, wherein in the cross section, the first conductive pad exposed by the first isolation layer is provided with a fourth width, and the fourth width is greater than 1/2 of the first width.

4. The semiconductor structure according to claim 1, wherein the semiconductor structure further comprises a first solder layer, and the first solder layer is at least formed on the first isolation layer and is adjacent to the first connection layer.

5. The semiconductor structure according to claim 4, wherein the first solder layer covers a surface of the first conductive bump.

6. The semiconductor structure according to claim 1, wherein the semiconductor structure is further provided with a second surface, the second surface being opposite to the first surface, and the second surface being provided with a second conductive pad and a second isolation layer surrounding the second conductive pad;
a second connection layer disposed on the second conductive pad and on the second isolation layer;
a second conductive bump disposed on the second connection layer and disposed corresponding to the second conductive pad, in a cross section perpendicular to the second surface, a width of the second connection layer being less than a width of the second conductive bump; and
a second solder layer at least formed on the second isolation layer and adjacent to the second connection layer.

7. A semiconductor package, comprising a plurality of semiconductor structures connected to each other, each of the plurality of semiconductor structures comprising:
a first surface, the first surface being provided with a first conductive pad and a first isolation layer, and the first isolation layer at least partially exposing a surface of the first conductive pad;
a first connection layer disposed on the surface of the first conductive pad exposed to the first isolation layer, the first connection layer being further disposed on the first isolation layer; and
a first conductive bump, the first conductive bump being disposed on the first connection layer and disposed corresponding to the first conductive pad, wherein
in a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width;
first surfaces of at least two adjacent semiconductor structures are directly opposite to each other and are electrically connected through respective first conductive bumps.

8. The package according to claim 7, wherein in each of the plurality of semiconductor structures, the absolute value of the difference between the first width and the third width is less than an absolute value of a difference between the second width and the third width.

9. The package according to claim 7, wherein the package further comprises: a first solder layer disposed between the first conductive bumps of the at least two adjacent semiconductor structures whose first surfaces are directly opposite to each other, and the first solder layer is further formed on first isolation layers of the at least two adjacent semiconductor structures and is adjacent to first connection layers.

10. The package according to claim 7, wherein each of the plurality of semiconductor structures is further provided with a second surface opposite to the first surface, in the package, second surfaces of at least two adjacent semiconductor structures are directly opposite to each other, a first spacing is provided between the at least two adjacent semiconductor structures whose first surfaces are directly opposite to each other, a second spacing is provided between the at least two adjacent semiconductor structures whose second surfaces are directly opposite to each other, and in a direction in which the semiconductor structures are connected to each other, the first spacing is greater than the second spacing.

11. The package according to claim 10, wherein the second surface of each of the plurality of semiconductor structures is provided with a second conductive pad and a second isolation layer surrounding the second conductive pad; the package comprises:
a second connection layer, the second connection layer being disposed on the second conductive pad and on the second isolation layer; and
a second conductive bump, the second conductive bump being disposed on the second connection layer and disposed corresponding to the second conductive pad, in a cross section perpendicular to the second surface, a width of the second connection layer being less than a width of the second conductive bump; and
the package further comprises a second solder layer disposed between the at least two adjacent semiconductor structures whose second surfaces are directly opposite to each other, and the second solder layer is further formed on second isolation layers of the at least two adjacent semiconductor structures and is adjacent to second connection layers.

12. The package according to claim 10, wherein the first surface is a front surface of the semiconductor structure, and the second surface is a back surface of the semiconductor structure.

13. A method for forming a semiconductor structure, comprising:
providing a semiconductor base substrate, and disposing a first conductive pad and a first isolation layer covering a part of the first conductive pad on the base substrate to form a first surface;
forming an initial first connection layer on the first surface, the initial first connection layer covering surfaces of the first conductive pad and the first isolation layer;
forming a first conductive bump on the initial first connection layer, the first conductive bump being disposed corresponding to the first conductive pad; and
removing a part of the initial first connection layer, and retaining a part of the initial first connection layer located between the first conductive bump and the first conductive pad to form a first connection layer, wherein
in a cross section perpendicular to the first surface, the first conductive pad is provided with a first width, the first connection layer is provided with a second width, the first conductive bump is provided with a third width, the second width is a sum of a width of the first connection layer on the first isolation layer and a width of the first connection layer on the first conductive pad, and an absolute value of a difference between the first width and the second width is greater than an absolute value of a difference between the first width and the third width.

14. The forming method according to claim 13, wherein before or after removing the part of the initial first connection layer, the method further comprises: treating a side wall of the first conductive bump and an exposed surface of the first isolation layer with plasma, the side wall of the first conductive bump being treated with microwave plasma, and the exposed surface of the first isolation layer being treated with radio frequency plasma.

15. The forming method according to claim 14, wherein a first solder layer is formed on the first conductive bump, and the first solder layer is reflowed such that the first solder layer is at least formed on the first isolation layer and is adjacent to the first connection layer.
